(19) United States
(12) Patent Application Publication
(10) Pub. No.: US 2025/0374775 A1
(43) Pub. Date: Dec. 4, 2025

(54) DISPLAY PANEL, ELECTRIC APPARATUS AND METHOD OF MANUFACTURING DISPLAY PANEL

(71) Applicant: Samsung Display Co., LTD., Yongin-si (KR)

(72) Inventors: Changwoo Shim, Yongin-si (KR); Sangtae Ahn, Yongin-si (KR); Yejoo Jun, Yongin-si (KR); Seungyeon Chae, Yongin-si (KR)

(21) Appl. No.: 19/000,344

(22) Filed: Dec. 23, 2024

(30) Foreign Application Priority Data
May 31, 2024 (KR) 10-2024-0071785

(51) Int. Cl. H10K 59/131; H10K 59/12; H10K 59/80; H10K 102/00

(52) U.S. Cl. CPC H10K 59/131; H10K 59/1201; H10K 59/871; H10K 2102/311

(57) ABSTRACT

A display panel includes: a substrate including a display area and a peripheral area outside the display area; a pad terminal section on the substrate; a driving element on the pad terminal section; and a protective layer on the substrate and spaced apart from the pad terminal section.

### CROSS-REFERENCE TO RELATED APPLICATION

The present application claims priority to and the benefit of Korean Patent Application No. 10-2024-0071785, filed on May 31, 2024, in the Korean Intellectual Property Office, the entire disclosure of which is incorporated herein by reference.

### BACKGROUND

### 1. Field

Aspects of some embodiments relate to an apparatus and a method.

### 2. Description of the Related Art

Mobile electronic apparatuses are widely used. As mobile electronic apparatuses, recently, tablet personal computers (PCs) have been widely used as well as miniaturized electronic apparatuses such as mobile phones.

To support various functions, for example, to provide a user with visual information, such as images, mobile electronic apparatuses may include a display apparatus. Recently, as the parts configured to drive a display panel have been miniaturized, the proportion of the display panel in an electronic apparatus has gradually increased and a structure that may bend to form a preset angle from a flat state is also under development.

The above information disclosed in this Background section is only for enhancement of understanding of the background and therefore the information discussed in this Background section does not necessarily constitute prior art.

### SUMMARY

Aspects of some embodiments relate to an apparatus and a method, and for example, to a display panel, electronic apparatus and a method of manufacturing the display panel.

An integrated circuit element may be located on a substrate of a display panel and connected to a plurality of pad terminals located on the substrate. In this case, before the integrated circuit element is connected to the pad terminal, a protective film may be temporarily attached to the display panel to protect the display panel from the outside, and the protective film may be removed to perform a next processing operation. In this case, when the protective film is removed, the pad terminal may be damaged. One or more embodiments include a display panel, electronic apparatus configured to protect a pad terminal, and a method of manufacturing the display panel.

Additional aspects will be set forth in part in the description which follows and, in part, will be apparent from the description, or may be learned by practice of the presented embodiments of the disclosure.

According to one or more embodiments, a display panel includes a substrate including a display area and a peripheral area arranged outside the display area, a pad terminal section on the substrate, a driving element being on the pad terminal section, and a protective layer on the substrate and arranged to be apart from the pad terminal section.

According to some embodiments, the protective layer may have a closed loop shape to surround the pad terminal section.

According to some embodiments, the protective layer may be provided in plurality, and the plurality of protective layers may be on an arbitrary closed loop surrounding the pad terminal section.

According to some embodiments, the display panel may further include a terminal section on the substrate and apart from the pad terminal section, wherein at least a portion of the protective layer may be on a lateral surface of the terminal section.

According to some embodiments, the display panel may further include a bending area arranged in the peripheral area and bending.

According to some embodiments, the display panel may further include a dam part arranged in the bending area, wherein at least a portion of the protective layer may be on a lateral surface of the dam part.

According to some embodiments, the substrate may further include an opening area arranged in the display area, and a non-display area surrounding at least a portion of the opening area, wherein the protective layer may be arranged in the non-display area.

According to some embodiments, an adhesive force of the protective layer may be in a range of about 10 gf/inch and about 150 gf/inch.

According to some embodiments, the protective layer may be cured by an ultraviolet ray.

According to one or more embodiments, an electronic apparatus includes a display panel displaying image, wherein the display panel includes a substrate including a display area and a peripheral area arranged outside the display area, a pad terminal section on the substrate, a driving element being on the pad terminal section, and a protective layer on the substrate and arranged to be apart from the pad terminal section.

According to some embodiments, the protective layer may have a closed loop shape to surround the pad terminal section.

According to some embodiments, the protective layer may be provided in plurality, and the plurality of protective layers may be on an arbitrary closed loop surrounding the pad terminal section.

According to some embodiments, the display panel may further include a terminal section on the substrate and apart from the pad terminal section, wherein at least a portion of the protective layer may be on a lateral surface of the terminal section.

According to some embodiments, the display panel may further include a bending area arranged in the peripheral area and bending.

According to some embodiments, the display panel may further include a dam part arranged in the bending area, wherein at least a portion of the protective layer may be on a lateral surface of the dam part.

According to some embodiments, the substrate may further include an opening area arranged in the display area, and a non-display area surrounding at least a portion of the opening area, wherein the protective layer may be arranged in the non-display area.

According to some embodiments, an adhesive force of the protective layer may be in a range of about 10 gf/inch and about 150 gf/inch.

According to some embodiments, the protective layer may be cured by an ultraviolet ray.

According to one or more embodiments, a method of manufacturing a display panel includes arranging a protective layer on a substrate, curing the protective layer using an ultraviolet ray, arranging a protective film on the substrate, and removing at least a portion of the protective layer by removing the protective film.

According to some embodiments, the protective layer may be configured to shield a pad terminal section on the substrate.

According to some embodiments, an adhesive force of a first region of the protective layer may be different from an adhesive force of a second region of the protective layer outside the first region.

According to some embodiments, the adhesive force of the first region may be less than the adhesive force of the second region.

According to some embodiments, the adhesive force of the first region may be in a range of about 5 gf/inch to about 10 gf/inch, and the adhesive force of the second region may be in a range of about 10 gf/inch to about 150 gf/inch.

According to some embodiments, a distance from an end of the protective layer to a boundary between the first region and the second region may be 0.1 or less of a total length of the protective layer.

According to some embodiments, the protective layer may be supplied through a nozzle.

According to some embodiments, the protective film may include a protective film base, and an adhesive layer between the protective film base and the substrate.

According to some embodiments, the protective film base may include at least one of polyethylene terephthalate, polypropylene, polycarbonate, polyethylene, or polyvinyl chloride.

According to some embodiments, the adhesive layer may include at least one of silicon, acryl or polyurethane.

According to some embodiments, the method may further include removing at least a portion of the protective film, at least a portion of the protective layer, and at least a portion of the substrate by irradiating a laser beam to the protective film.

These and/or other aspects will become apparent and more readily appreciated from the following detailed description of the embodiments, the accompanying drawings, and claims.

These general and specific aspects may be implemented by using a system, a method, a computer program, or a combination of a certain system, method, and computer program.

### BRIEF DESCRIPTION OF THE DRAWINGS

The above and other aspects, features, and characteristics of certain embodiments of the disclosure will be more apparent from the following description taken in conjunction with the accompanying drawings, in which:

FIG. 1 is a perspective view of a electronic apparatus according to some embodiments;

FIG. 2 is a plan view of a display panel and a printed circuit board of the electronic apparatus shown in FIG. 1;

FIG. 3 is an equivalent circuit diagram of a sub-pixel circuit electrically connected to a light-emitting diode provided to a display panel according to some embodiments;

FIGS. 4A and 4B are cross-sectional views of a portion of a display panel, taken along the line A-A′ of FIG. 2;

FIGS. 5A and 5B are plan views of a pad terminal portion of the display panel shown in FIG. 2;

FIGS. 6A to 6C are cross-sectional views showing an order of manufacturing the display panel shown in FIG. 2;

FIG. 7 is a cross-sectional view showing a portion of an order of manufacturing a display panel according to some embodiments;

FIG. 8 is a cross-sectional view of a pad terminal of a display panel according to some embodiments;

FIG. 9 is a plan view of a portion of a display panel according to some embodiments;

FIG. 10 is a cross-sectional view of a portion of a display panel, taken along the line H-H′ of FIG. 9;

FIGS. 11A to 11D are cross-sectional views showing an order of manufacturing the display panel shown in FIG. 9; and

FIG. 12 is a plan view of a portion of a display panel according to some embodiments.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As the disclosure allows for various changes and numerous embodiments, certain embodiments will be illustrated in the drawings and described in the written description. Effects and features of the disclosure, and methods for achieving them will be clarified with reference to embodiments described below in detail with reference to the drawings. However, the disclosure is not limited to the following embodiments and may be embodied in various forms.

Hereinafter, embodiments will be described with reference to the accompanying drawings, wherein like reference numerals refer to like elements throughout and a repeated description thereof is omitted.

While such terms as “first” and “second” may be used to describe various elements, such elements must not be limited to the above terms. The above terms are used to distinguish one element from another.

The singular forms “a,” “an,” and “the” as used herein are intended to include the plural forms as well unless the context clearly indicates otherwise.

It will be understood that the terms “comprise,” “comprising,” “include” and/or “including” as used herein specify the presence of stated features or elements but do not preclude the addition of one or more other features or elements.

It will be further understood that, when a layer, region, or element is referred to as being “on” another layer, region, or element, it can be directly or indirectly on the other layer, region, or element. That is, for example, intervening layers, regions, or elements may be present.

Sizes of elements in the drawings may be exaggerated or reduced for convenience of explanation. As an example, the size and thickness of each element shown in the drawings are arbitrarily represented for convenience of description, and thus, the disclosure is not necessarily limited thereto.

The x-axis, the y-axis and the z-axis are not limited to three axes of the rectangular coordinate system, and may be interpreted in a broader sense. For example, the x-axis, the y-axis, and the z-axis may be perpendicular to one another, or may represent different orientations that are not perpendicular to one another.

In the case where a certain embodiment may be implemented differently, a specific process order may be performed in the order different from the described order. As an example, two processes successively described may be simultaneously performed substantially and performed in the opposite order.

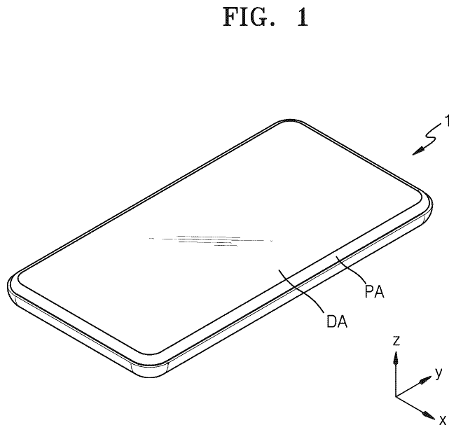

FIG. 1 is a perspective view of a electronic apparatus 1 according to some embodiments.

Referring to FIG. 1, the electronic apparatus 1 is a portable electronic apparatus for displaying moving images (e.g., video images) or still images (e.g., static images) and may include portable electronic apparatuses such as mobile phones, smartphones, tablet personal computers, mobile communication terminals, electronic organizers, electronic books, portable multimedia players (PMPs), navigations, ultra mobile personal computers (UMPCs), or the like. Alternatively, the electronic apparatus 1 may be various products such as televisions, notebook computers, monitors, advertisement boards, Internet of things (IoTs) device, and the like. In addition, the electronic apparatus 1 according to some embodiments may be wearable devices including smartwatches, watchphones, glasses-type displays, or head-mounted displays (HMDs), or a part of such a wearable device. In addition, according to some embodiments, the electronic apparatus 1 may be instrument panels for automobiles, center fascias for automobiles, center information displays (CIDs) arranged on a dashboard, room mirror displays that replace side mirrors of automobiles, an entertainment system arranged on the backside of front seats for backseat passengers in automobiles, a head-up display (HUD) installed at the front of a vehicle or projected on a front window glass, and/or a computer generated hologram augmented reality head up display (CGH AR HUD).

The electronic apparatus 1 may have a rectangular shape in a plan view. As an example, the electronic apparatus 1 may have a quadrangular shape having short sides of the x direction and long sides of the y direction in a plan view. A corner where the short side of the x direction meets the long side of the y direction may be round to have a preset curvature or formed to have a right angle. A planar shape of the electronic apparatus 1 is not limited to a rectangle, but may be other polygons, ellipses, or irregular shapes.

The electronic apparatus 1 may include a display area DA and a peripheral area PA outside (e.g., in a periphery or outside a footprint of) the display area DA in a plan view, wherein the display area DA is configured to display images by using light emitted from sub-pixels.

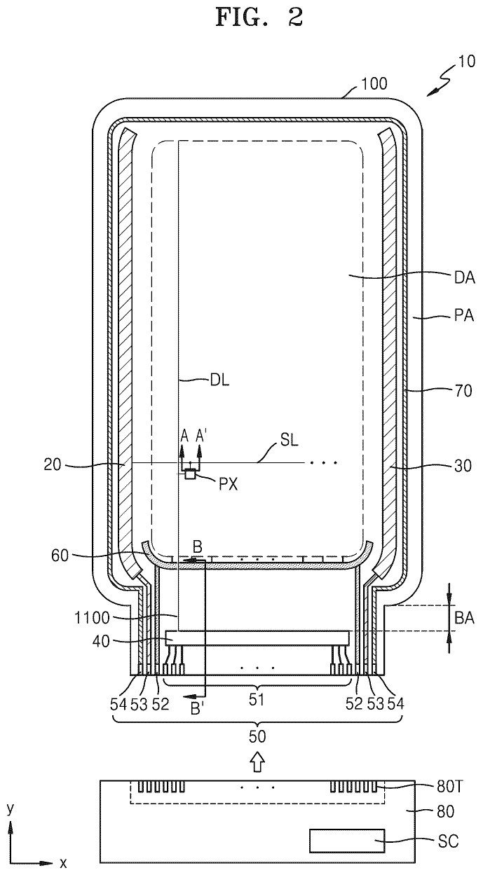

FIG. 2 is a plan view of a display panel 10 and a flexible printed circuit board 80 of the electronic apparatus 1 shown in FIG. 1.

Referring to FIG. 2, the electronic apparatus 1 may include the display panel 10 and the flexible printed circuit board 80. In the display panel 10, sub-pixels PX arranged in the display area DA may be configured to emit red, green, and blue light by using light-emitting diodes arranged in relevant positions corresponding to respective sub-pixels PX. Transistors and signal lines, for example, data lines DL and scan lines SL may be arranged in the display area DA, wherein the transistors are electrically connected to the light-emitting diodes, and the signal lines are electrically connected to a storage capacitor. The data lines DL may extend in a y direction in the display area DA, and the scan lines SL may extend in an x direction in the display area DA. Although FIG. 2 illustrates a single sub-pixel PX, a single scan line SL, and a single data line DL, for convenience of illustration, as a person having ordinary skill in the art would recognize, the display panel 10 may include any suitable number of sub-pixels PX, scan lines SL, and data lines DL according to the design and size of the display panel 10.

The peripheral area PA may be outside the display area DA and may surround the display area DA entirely.

First and second scan drivers 20 and 30 may be arranged in the peripheral area PA and electrically connected to the scan lines SL. According to some embodiments, some of the scan lines SL may be electrically connected to the first scan driver 20, and the rest may be connected to the second scan driver 30. The first and second drivers 20 and 30 may be configured to generate scan signals, and the generated scan signals may be transferred to a transistor electrically connected to a light-emitting diode through the scan line SL.

The first and second drivers 20 and 30 may be arranged on two opposite sides of the display area DA. As an example, as shown in FIG. 2, the first scan driver 20 may be arranged on the left of the display area DA, and the second scan driver 30 may be arranged on the right of the display area DA. According to some embodiments, one of the first and second drivers 20 and 30 may be omitted.

A driving voltage supply line 60 may be arranged in the peripheral area PA. The driving voltage supply line 60 may be arranged between one side of a substrate 100 in which a terminal section 50 is arranged, and the display area DA.

A common voltage supply line 70 may be arranged in the peripheral area PA and may have a loop shape having one open side and extending along the display area DA. The common voltage supply line 70 may have an overall U-shape as shown in FIG. 2. The common voltage supply line 70 may extend along the other sides except for one side of the substrate 100 in which the terminal section 50 is arranged. Accordingly, the first scan driver 20 may be arranged between one portion of the common voltage supply line 70 and the display area DA, and the second scan driver 30 may be arranged between another portion of the common voltage supply line 70 and the display area DA.

An integrated circuit element 40 may be arranged in the peripheral area PA. The integrated circuit element 40 may be arranged between one side of the substrate 110 in which the terminal section 50 is arranged, and the display area DA. The integrated circuit element 40 may include a data driver. In the present specification, the integrated circuit element 40 may represent a data driver. The integrated circuit element 40 may be electrically connected to a pad terminal located therebelow. Data signals generated by the integrated circuit element 40, for example, the data driver, may be transferred to a signal line arranged in the display area DA, for example, the data line DL through a connection line 1100 arranged in a panout area. The panout area POA is a portion of the peripheral area PA and corresponds to a region between the integrated circuit element 40 and the display area DA.

The terminal section 50 may include terminals 51, 52, 53, and 54. The terminals 51, 52, 53, and 54 may be exposed by not being covered by an insulating layer and electrically connected to a controller SC located on the flexible printed circuit board 80. The flexible printed circuit board 80 may include counter terminals 80T corresponding to the terminal section 50. The counter terminals 80T of the flexible printed circuit board 80 may be electrically connected to the terminals 51, 52, 53, and 54. The controller SC may be configured to generate control signals for controlling the first and second scan drivers 20 and 30 and the integrated circuit element 40. The generated control signals may be transferred to the first and second scan drivers 20 and 30 and the integrated circuit element 40 through the terminals 51 and 53. The controller SC may be configured to respectively transfer a driving voltage and a common voltage to the driving voltage supply line 60 and the common voltage supply line 70 through the terminals 52 and 54. According to some embodiments, at least a portion of the display panel 10 may bend. As an example, a portion of the display panel 10 may bend such that a portion of the peripheral area PA in which the integrated circuit element 40 is arranged is arranged on the backside of the display area DA. In this case, the display panel 10 may include a bending area BA in which a portion of the peripheral area PA bends. The bending area BA may be arranged between the display area DA and the integrated circuit element 40.

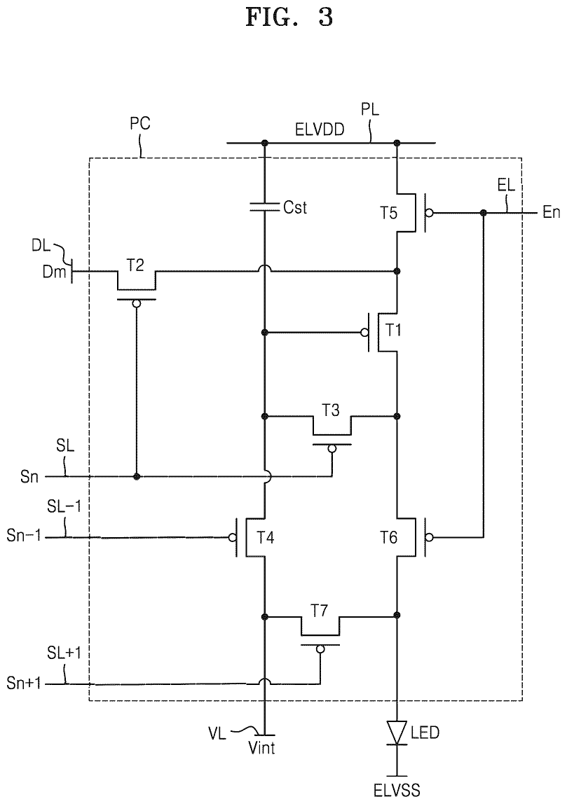

FIG. 3 is an equivalent circuit diagram of a sub-pixel circuit electrically connected to a light-emitting diode provided to the display panel 10 according to some embodiments. Although FIG. 3 illustrates various components in a sub-pixel circuit, embodiments according to the present disclosure are not limited thereto, and according to various embodiments the sub-pixel may include additional components or fewer components without departing from the spirit and scope of embodiments according to the present disclosure.

Referring to FIG. 3, as described above with reference to FIG. 2, each sub-pixel PX (see FIG. 2) may be configured to emit light using a light-emitting diode. A light-emitting diode may be electrically connected to a sub-pixel circuit PC.

The sub-pixel circuit PC may include a first thin-film transistor T1, a second thin-film transistor T2, a third thin-film transistor T3, a fourth thin-film transistor T4, a fifth thin-film transistor T5, a sixth thin-film transistor T6, a seventh thin-film transistor T7, and a storage capacitor Cst.

The second thin-film transistor T2 is a switching thin-film transistor, may be connected to the scan line SL and the data line DL, and configured to transfer a data voltage (or a data signal Dm) to the first thin-film transistor T1 based on a switching voltage (or a switching signal Sn), the data voltage being input from the data line DL, and the switching voltage being input from the scan line SL. The storage capacitor Cst may be connected to the second thin-film transistor T2 and a driving voltage line PL and configured to store a voltage corresponding to a difference between a voltage transferred from the second thin-film transistor T2 and a driving voltage ELVDD supplied to the driving voltage line PL.

The first thin-film transistor T1 is a driving thin-film transistor, may be connected to the driving voltage line PL and the storage capacitor Cst, and configured to control a driving current according to the voltage stored in the storage capacitor Cst, the driving current flowing from the driving voltage line PL to a light-emitting diode LED. The light-emitting diode LED may be configured to emit light having a preset brightness corresponding to the driving current. A second electrode (e.g., a cathode) of the light-emitting diode LED may be configured to receive a common voltage ELVSS.

The third thin-film transistor T3 is a compensation thin-film transistor, and a gate electrode of the third thin-film transistor T3 may be connected to the scan line SL. A source electrode (or a drain electrode) of the third thin-film transistor T3 may be connected to a first electrode of the light-emitting diode LED through the sixth thin-film transistor T6 while being connected to a drain electrode (or a source electrode) of the first thin-film transistor T1. A drain electrode (or a source electrode) of the third thin-film transistor T3 may be connected to one of the electrodes of the storage capacitor Cst, a source electrode (or a drain electrode) of the fourth initialization thin-film transistor T4, and the gate electrode of the first thin-film transistor T1. The third thin-film transistor T3 is turned on according to a scan signal Sn received through the scan line SL and diode-connects the first thin-film transistor T1 by connecting the gate electrode and the drain electrode of the first thin-film transistor T1 to each other.

The fourth thin-film transistor T4 is an initialization thin-film transistor and a gate electrode thereof may be connected to a previous scan line SL−1. A drain electrode (or a source electrode) of the fourth thin-film transistor T4 may be connected to an initialization voltage line VL. A drain electrode (or a source electrode) of the fourth thin-film transistor T4 may be connected to one of the electrodes of the storage capacitor Cst, a drain electrode (or a source electrode) of the third initialization thin-film transistor T3, and the gate electrode of the first thin-film transistor T1. The fourth thin-film transistor T4 may be turned on according to a previous scan signal Sn−1 received through the previous scan line SL−1 and may perform an initialization operation of initializing the voltage of the gate electrode of the first thin-film transistor T1 by transferring an initialization voltage Vint to the gate electrode of the first thin-film transistor T1.

The fifth thin-film transistor T5 is an operation control thin-film transistor, and a gate electrode thereof may be connected to an emission control line EL. A source electrode (or a drain electrode) of the fifth thin-film transistor T5 may be connected to the driving voltage line PL. The drain electrode (or the source electrode) of the fifth thin-film transistor T5 may be connected to the source electrode (or the drain electrode) of the first thin-film transistor T1, and the drain electrode (or the source electrode) of the second thin-film transistor T2.

The sixth thin-film transistor T6 is an emission control thin-film transistor, and a gate electrode thereof may be connected to the emission control line EL. A source electrode (or a drain electrode) of the sixth thin-film transistor T6 may be connected to the drain electrode (or the source electrode) of the first thin-film transistor T1, and the source electrode (or the drain electrode) of the third thin-film transistor T3. The drain electrode (or the source electrode) of the sixth thin-film transistor T6 may be electrically connected to the first electrode of the light-emitting diode LED. The fifth thin-film transistor T5 and the sixth thin-film transistor T6 may be simultaneously turned on according to an emission control signal En transferred through the emission control line EL, the driving voltage ELVDD is transferred to the light-emitting element LED, and the driving current flows through the light-emitting element LED.

The seventh thin-film transistor T7 may be an initialization thin-film transistor configured to initialize the first electrode of the light-emitting diode LED. A gate electrode of the seventh thin-film transistor T7 may be connected to a next scan line SL+1. The source electrode (or the drain electrode) of the seventh thin-film transistor T7 may be connected to the first electrode of the light-emitting diode LED. The drain electrode (or the source electrode) of the seventh thin-film transistor T7 may be connected to the initialization voltage line VL. The seventh thin-film transistor T7 may be turned on according to a next scan signal Sn+1 transferred through the next scan line SL+1 to initialize the first electrode of the light-emitting element LED.

Although it is shown in FIG. 3 that the fourth thin-film transistor T4 and the seventh thin-film transistor T7 are respectively connected to the previous scan line SL−1 and the next scan line SL+1, both the fourth thin-film transistor T4 and the seventh thin-film transistor T7 may be connected to the previous scan line SL−1 and driven according to a previous scan signal Sn−1 according to some embodiments.

The other electrode of the storage capacitor Cst may be connected to the driving voltage line PL. One of the electrodes of the storage capacitor Cst may be connected to the gate electrode of the first thin-film transistor T1, the drain electrode (or the source electrode) of the third thin-film transistor T3, and the source electrode (or the drain electrode) of the fourth thin-film transistor T4 together.

The second electrode (e.g., a cathode) of the light-emitting diode LED is configured to receive the common power voltage ELVSS. The light-emitting diode LED is configured to emit light by receiving the driving current from the first thin-film transistor T1.

The light-emitting diode LED may be an organic light-emitting diode including an organic material as an emission material. According to some embodiments, the light-emitting diode may be an inorganic light-emitting diode including an inorganic material. The inorganic light-emitting diode may include a PN diode including inorganic material semiconductor-based materials. When a forward voltage is applied to a PN-junction diode, holes and electrons are injected and energy created by recombination of the holes and the electrons is converted to light energy, and thus, light of a preset color may be emitted. The inorganic light-emitting diode may have a width of several micrometers to hundreds of micrometers, or several nanometers to hundreds of nanometers. According to some embodiments, the light-emitting diode LED may be a quantum-dot light-emitting diode. As described above, an emission layer of the light-emitting diode LED may include an organic material, an inorganic material, quantum dots, an organic material and quantum dots, or inorganic material and quantum dots. Hereinafter, for convenience of description, the case where the light-emitting diode LED includes an organic light-emitting diode is described.

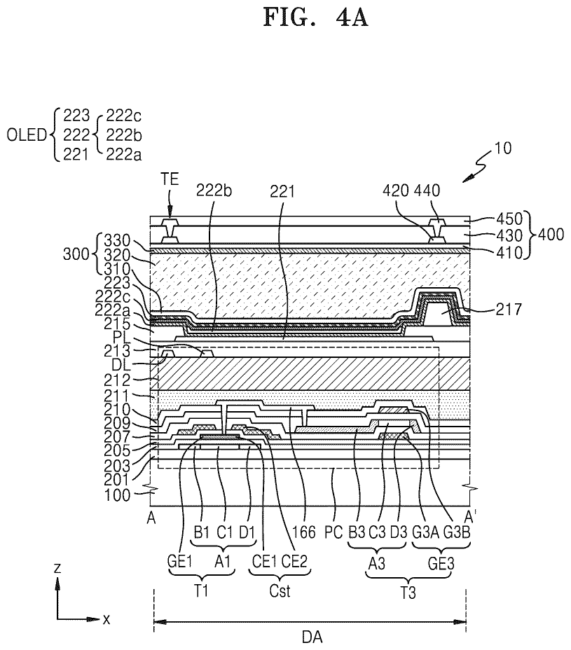

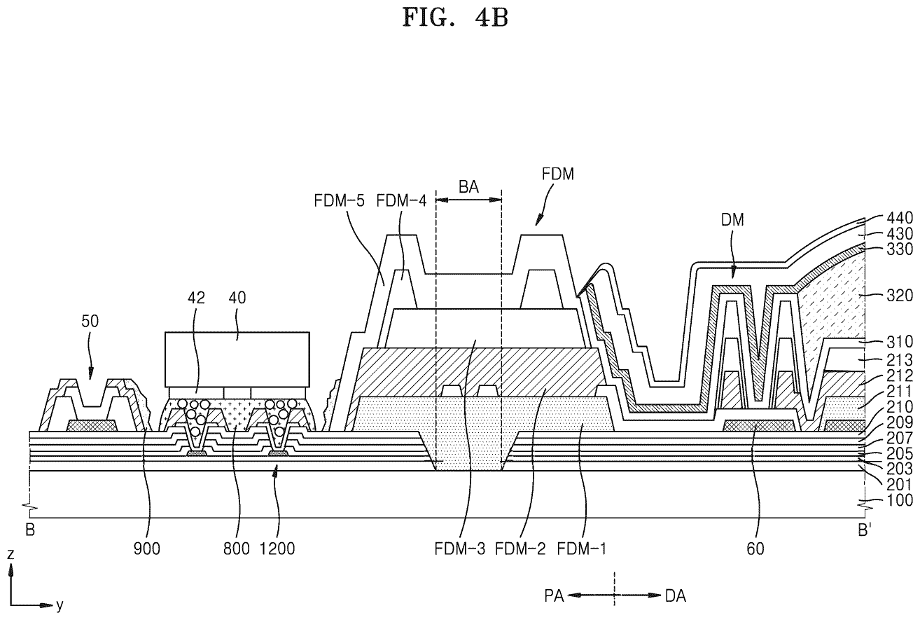

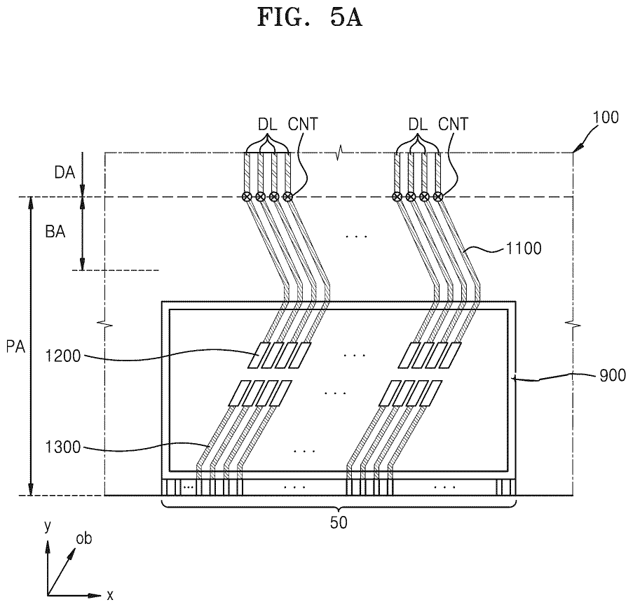

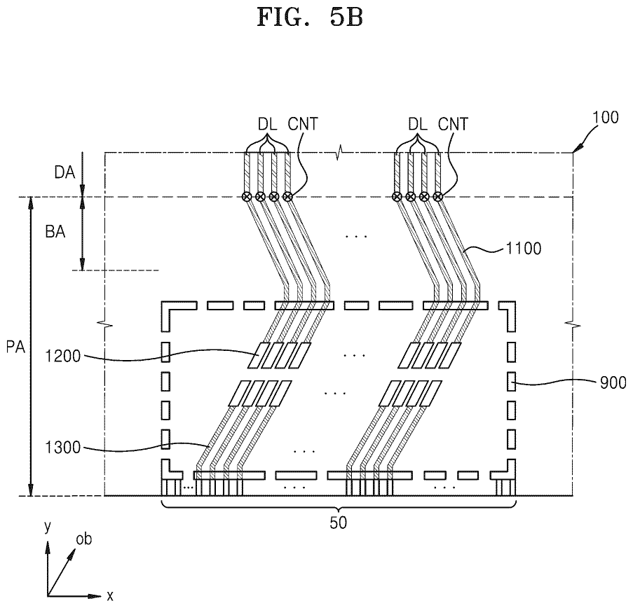

FIG. 4A is a cross-sectional view of a portion of the display panel 10, taken along the line A-A′ of FIG. 2. FIG. 4B is a cross-sectional view of a portion of the display panel 10, taken along the line B-B′ of FIG. 2. FIG. 5A is a plan view of a pad terminal portion of the display panel 10 shown in FIG. 2.

Referring to FIGS. 4A to 5A, the display panel 10 may include the sub-pixel circuit PC arranged in the display area DA of the display panel 10, the light-emitting diode, a first dam part DM, a second dam part FDM, a pad terminal 1200, the terminal section 50, and a protective layer 900. In this case, the light-emitting diode may include an organic light-emitting diode OLED.

The substrate 100 may include glass or polymer resin. According to some embodiments, the substrate 100 may have a stack structure in which a base layer including a polymer resin and a barrier layer including an inorganic insulating material such as silicon oxide or silicon nitride are alternately stacked. In the case where the substrate 100 includes the stack structure of the base layer of the polymer resin and the barrier layer of the inorganic insulating material as described above, because the flexibility of the electronic apparatus 1 improves as described above with reference to FIG. 1, a foldable electronic apparatus 1 may be provided.

The polymer resin may include polyethersulfone, polyarylate, polyetherimide, polyethylene naphthalate, polyethylene terephthalate, polyphenylene sulfide, polyimide, polycarbonate, cellulose tri acetate, cellulose acetate propionate, or the like.

The sub-pixel circuit PC may be formed on the substrate 100, and the light-emitting diode, for example, the organic light-emitting diode OLED, may be formed on the sub-pixel circuit PC.

A buffer layer 201 may be formed on the substrate 100 before the sub-pixel circuit PC is formed to prevent or reduce instances of impurities or contaminants penetrating the sub-pixel circuit PC. The buffer layer 201 may include an inorganic insulating material such as silicon nitride, silicon oxynitride, and silicon oxide, and include a single-layered structure or a multi-layered structure including the above inorganic insulating materials.

As described above with reference to FIG. 3, the sub-pixel circuit PC may include the plurality of transistors and the storage capacitor. With regard to this, FIG. 4 shows the first thin-film transistor T1, the third thin-film transistor T3, and the storage capacitor Cst.

The first thin-film transistor T1 may include a semiconductor layer (referred to as a first semiconductor layer A1) on the buffer layer 201, and a gate electrode (referred to as a first gate electrode GE1) overlapping a channel region C1 of the first semiconductor layer A1. The first semiconductor layer A1 may include a silicon-based semiconductor material, for example, polycrystalline silicon. The first semiconductor layer A1 may include the channel region C1, a first region B1, and a second region D1 respectively located on two opposite sides of the channel region C1. The first region B1 and the second region D1 are regions including impurities of higher concentration than that of the channel region C1. One of the first region B1 and the second region D1 may correspond to a source region, and the other may correspond to a drain region.

A first gate insulating layer 203 may be located between the first semiconductor layer A1 and the first gate electrode GE1. The first gate insulating layer 203 may include an inorganic insulating material such as silicon nitride, silicon oxynitride, and silicon oxide, and include a single-layered structure or a multi-layered structure including the above inorganic insulating materials.

The first gate electrode GE1 may include a conductive material including molybdenum (Mo), aluminum (Al), copper (Cu), and titanium (Ti) and have a single-layered structure or a multi-layered structure including the above materials.

The storage capacitor Cst may include a lower electrode CE1 and an upper electrode CE2 overlapping each other. According to some embodiments, the lower electrode CE1 of the storage capacitor Cst may include the first gate electrode GE1. In other words, the first gate electrode GE1 may include the lower electrode CE1 of the storage capacitor Cst. As an example, the first gate electrode GE1 and the lower electrode CE1 of the storage capacitor Cst may be integrally formed.

A first interlayer insulating layer 205 may be located between the lower electrode CE1 and the upper electrode CE2 of the storage capacitor Cst. The first interlayer insulating layer 205 may include an inorganic insulating material such as silicon nitride, silicon oxynitride, and silicon oxide, and include a single-layered structure or a multi-layered structure including the above inorganic insulating materials.

The upper electrode CE2 of the storage capacitor Cst may include a conductive material of a low-resistance material such as molybdenum (Mo), aluminum (Al), copper (Cu) and/or titanium (Ti), and have a single-layered structure or a multi-layered structure including the above materials.

A second interlayer insulating layer 207 may be located on the storage capacitor Cst. The second interlayer insulating layer 207 may include an inorganic insulating material such as silicon nitride, silicon oxynitride, and silicon oxide, and include a single-layered structure or a multi-layered structure including the above inorganic insulating materials.

A semiconductor layer (referred to as a third semiconductor layer A3) of the third thin-film transistor T3 may be located on the second interlayer insulating layer 207. The third semiconductor layer A3 may include an oxide-based semiconductor material. As an example, the third semiconductor layer A3 may include Zn-oxide-based material, for example, include Zn-oxide, In—Zn oxide, and Ga—In—Zn oxide. According to some embodiments, the third semiconductor layer A3 may include In—Ga—Zn—O (IGZO), In—Sn—Zn—O (ITZO), or In—Ga—Sn—Zn—O (IGTZO) semiconductor containing metal such as indium (In), gallium (Ga), and stannum (Sn) in ZnO.

The third semiconductor layer A3 may include a channel region C3, a first region B3, and a second region D3 respectively located on two opposite sides of the channel region C3. One of the first region B3 and the second region D3 may correspond to a source region, and the other may correspond to a drain region.

The third thin-film transistor T3 may include a gate electrode (referred to as a third gate electrode GE3, hereinafter) overlapping the channel region C3 of the third semiconductor layer A3. The third gate electrode GE3 may have a double gate structure including a lower gate electrode G3A and an upper gate electrode G3B, wherein the lower gate electrode G3A is below the third semiconductor layer A3, and the upper gate electrode G3B is over the channel region C3.

The lower gate electrode G3A may be on the same layer (e.g., the first interlayer insulating layer 205) as the upper electrode CE2 of the storage capacitor Cst. The lower gate electrode G3A may include the same material as a material of the upper electrode CE2 of the storage capacitor Cst.

The upper gate electrode G3B may be located over the third semiconductor layer A3 with a second gate insulating layer 209 therebetween. The second gate insulating layer 209 may include an inorganic insulating material such as silicon nitride, silicon oxynitride, and silicon oxide, and include a single-layered structure or a multi-layered structure including the above inorganic insulating materials.

A third interlayer insulating layer 210 may be located on the upper gate electrode G3B. The third interlayer insulating layer 210 may include an inorganic insulating material such as silicon oxynitride, and have a single layer or a multi-layer including the inorganic insulating materials.

Although FIG. 4A shows the first thin-film transistor T1 and the third thin-film transistor T3 among the plurality of thin-film transistors and the first semiconductor layer A1 and the third semiconductor layer A3 are located on different layers as described with reference to FIG. 3, the disclosure is not limited thereto.

The second, fifth, sixth, and seventh thin-film transistors T2, T5, T6, and T7 described with reference to FIG. 3 may have the same structure as the first thin-film transistor T1 described with reference to FIG. 4. As an example, the second, fifth, sixth, and seventh thin-film transistors T2, T5, T6, and T7 may include a semiconductor layer located on the same layer as the first semiconductor layer A1 of the first thin-film transistor T1, and a gate electrode located on the same layer as the first gate electrode GE1 of the first thin-film transistor T1. The semiconductor layers of the second, fifth, sixth, and seventh thin-film transistors T2, T5, T6, and T7 may be integrally connected to the first semiconductor layer A1.

The fourth thin-film transistor T4 (see FIG. 3) described with reference to FIG. 3 may have the same structure as that of the third thin-film transistor T3 described with reference to FIG. 4. As an example, the fourth thin-film transistor T4 may include a semiconductor layer located on the same layer as the third semiconductor layer A3 of the third thin-film transistor T3, and a gate electrode formed on the same layer as the third gate electrode GE3 of the third thin-film transistor T3. A semiconductor layer of the fourth thin-film transistor T4 may be integrally connected to the third semiconductor layer A3 of the third thin-film transistor T3.

The first thin-film transistor T1 may be electrically connected to the third thin-film transistor T3 through a node connection line 166. The node connection line 166 may be located on the third interlayer insulating layer 210. One side of the node connection line 166 may be connected to the first gate electrode GE1 of the first thin-film transistor T1, and the other side of the node connection line 166 may be connected to the third semiconductor layer A3 of the third thin-film transistor T3.

The node connection line 166 may include aluminum (Al), copper (Cu), and/or titanium (Ti), and include a single layer or a multi-layer including the above materials. As an example, the node connection line 166 may have a three-layered structure of titanium layer/aluminum layer/titanium layer.

A first organic insulating layer 211 may be located on the node connection line 166. The first organic insulating layer 211 may include an organic insulating material. The organic insulating material may include acryl, benzocyclobutene (BCB), polyimide, or hexamethyldisiloxane (HMDSO).

A second organic insulating layer 212 may be located on the first organic insulating layer 211. In this case, the second organic insulating layer 212 may include a material identical or similar to that of the first organic insulating layer 211. In addition, the second organic insulating layer 212 may be integrally formed with the first organic insulating layer 211, or formed separately from the first organic insulating layer 211 and stacked on the first organic insulating layer 211.

The data line DL and the driving voltage line PL may be located on the first organic insulating layer 211 or the second organic insulating layer 212, and may be covered by the second organic insulating layer 212 or a third organic insulating layer 213. Hereinafter, for convenience of description, the case where the data line DL and the driving voltage line PL are located on the second organic insulating layer 212 and covered by the third organic insulating layer 213 is mainly described in detail.

The data line DL and the driving voltage line PL may include aluminum (Al), copper (Cu), and/or titanium (Ti), and include a single layer or a multi-layer including the above materials. As an example, the data line DL and the driving voltage line PL may each have a three-layered structure of titanium layer/aluminum layer/titanium layer.

The third organic insulating layer 213 may include acryl, BCB, polyimide, and/or HMDSO. Although it is shown in FIG. 4 that the data line DL and the driving voltage line PL are located on the first organic insulating layer 211, the disclosure is not limited thereto. According to some embodiments, one of the data line DL and the driving voltage line PL may be located on the same layer (e.g., the third interlayer insulating layer 210) as the node connection line 166.

The light-emitting diode, for example, the organic light-emitting diode OLED, may be located on the third organic insulating layer 213.

A first electrode 221 of the organic light-emitting diode OLED may include a reflective layer including silver (Ag), magnesium (Mg), aluminum (Al), platinum (Pt), palladium (Pd), gold (Au), nickel (Ni), neodymium (Nd), iridium (Ir), chrome (Cr), or a compound thereof. According to some embodiments, the first electrode 221 may further include a conductive oxide material layer on and/or under the reflective layer. The conductive oxide material layer may include indium tin oxide (ITO), indium zinc oxide (IZO), zinc oxide (ZnO), indium oxide (In₂O₃), indium gallium oxide (IGO), and/or aluminum zinc oxide (AZO). According to some embodiments, the first electrode 221 may have a three-layered structure of ITO layer/Ag layer/ITO layer.

A bank layer 215 may be located on the first electrode 221. The bank layer 215 may include an opening that overlaps the first electrode 221 and cover the edges of the first electrode 221. The bank layer 215 may include an organic insulating material such as polyimide.

An intermediate layer 222 includes an emission layer 222b. The intermediate layer 222 may include a first functional layer 222a and/or a second functional layer 222c, wherein the first functional layer 222a is under the emission layer 222b, and the second functional layer 222c is on the emission layer 222b. The emission layer 222b may include a polymer organic material or a low-molecular weight organic material configured to emit light having a preset color. The second functional layer 222c may include an electron transport layer (ETL) and/or an electron injection layer (EIL). The first functional layer 222a and the second functional layer 222c may each include an organic material.

A second electrode 223 may include a conductive material having a low work function. As an example, the second electrode 223 may include a (semi) transparent layer including silver (Ag), magnesium (Mg), aluminum (Al), platinum (Pt), palladium (Pd), gold (Au), nickel (Ni), neodymium (Nd), iridium (Ir), chrome (Cr), or an alloy thereof. Alternatively, the second electrode 223 may further include a layer on the (semi) transparent layer, the layer including ITO, IZO, ZnO, or In₂O₃.

The emission layer 222b may be formed in the display area DA to overlap the first electrode 221 through the opening of the bank layer 215. In contrast, the first functional layer 222a, the second functional layer 222c, and the second electrode 223 may cover the display area DA entirely.

A spacer 217 may be formed on the bank layer 215. The spacer 217 may be formed together with the bank layer 215 during the same process as a process of forming the bank layer 215, or formed separately during a separate process. According to some embodiments, the spacer 217 may include an organic insulating material such as polyimide. Alternatively, the bank layer 215 may include an organic insulating material including a light-blocking dye, and the spacer 217 may include an organic insulating material such as polyimide.

The organic light-emitting diode OLED may be covered by an encapsulation layer 300. The encapsulation layer 300 may include at least one organic encapsulation layer and at least one inorganic encapsulation layer. According to some embodiments, it is shown in FIG. 4 that the encapsulation layer 300 includes first and second inorganic encapsulation layers 310 and 330, and an organic encapsulation layer 320 therebetween.

The first and second inorganic encapsulation layers 310 and 330 may include at least one inorganic material among aluminum oxide, titanium oxide, tantalum oxide, hafnium oxide, zinc oxide, silicon oxide, silicon nitride, silicon oxynitride, and the like. The first and second inorganic encapsulation layers 310 and 330 may include a single layer or a multi-layer including the above materials. The organic encapsulation layer 320 may include a polymer-based material. The polymer-based material may include an acryl-based resin, an epoxy-based resin, polyimide, and polyethylene. According to some embodiments, the organic encapsulation layer 320 may include acrylate.

The thickness of the first inorganic encapsulation layer 310 may be different from that of the second inorganic encapsulation layer 330. The thickness of the first inorganic encapsulation layer 310 may be greater than that of the second inorganic encapsulation layer 330. Alternatively, the thickness of the second inorganic encapsulation layer 330 may be greater than that of the first inorganic encapsulation layer 310, or the thickness of the first inorganic encapsulation layer 310 may be the same as that of the second inorganic encapsulation layer 330.

An input sensing layer 400 may be located on the encapsulation layer 300. The input sensing layer 400 may include touch electrodes TE and at least one touch insulating layer arranged in the display area DA. With regard to this, it is shown in FIG. 4 that the input sensing layer 400 includes a first touch insulating layer 410, a first conductive line 420, a second touch insulating layer 430, a second conductive line 440, and a third touch insulating layer 450, wherein the first touch insulating layer 410 is on the second inorganic encapsulation layer 330, the first conductive line 420 is on the first touch insulating layer 410, the second touch insulating layer 430 is on the first conductive line 420, the second conductive line 440 is on the second touch insulating layer 430, and the third touch insulating layer 450 is on the second conductive line 440.

The first touch insulating layer 410, the second touch insulating layer 430, and the third touch insulating layer 450 may each include an inorganic insulating material and/or an organic insulating material. According to some embodiments, the first touch insulating layer 410 and the second touch insulating layer 430 may each include an inorganic insulating material such as silicon oxide, silicon nitride, and/or silicon oxynitride, and the third touch insulating layer 450 may include an organic insulating material. At least one of the first touch insulating layer 410, the second touch insulating layer 430, or the third touch insulating layer 450 may extend from the display area DA to the peripheral area PA.

A touch electrode TE of the input sensing layer 400 may have a structure in which the first conductive line 420 is connected to the second conductive line 440. Alternatively, the touch electrode TE may include one of the first conductive line 420 and the second conductive line 440. In this case, the second touch insulating layer 430 may be omitted.

Each of the first conductive line 420 and the second conductive line 440 may include aluminum (Al), copper (Cu), and/or titanium (Ti), and include a single layer or a multi-layer including the above materials. As an example, each of the first conductive line 420 and the second conductive line 440 may have a triple-layered structure of titanium layer/aluminum layer/titanium layer.

According to some embodiments, at least one of the first conductive line 420 or the second conductive line 440 may extend from the display area DA to the peripheral area PA and be connected to at least one of the pad terminal 1200 or the terminal section 50.

The first dam part DM and the second dam part FDM may be arranged in the peripheral area PA. In this case, the first dam part DM and the second dam part FDM may be apart from each other. The first dam part DM may block flow of the organic encapsulation layer 320 by including at least one dam. That is, the first dam part DM may be configured to prevent or reduce instances of the organic encapsulation layer 320 flowing to the pad terminal 1200 when forming the organic encapsulation layer 320. The second dam part FDM may be arranged to overlap the bending area BA. In this case, the second dam part FDM may overlap a partially removed region of the inorganic insulating layer located on the substrate 100. As an example, the second dam part FDM may overlap at least partially removed portion among the buffer layer 201, the first gate insulating layer 203, the first interlayer insulating layer 205, the second interlayer insulating layer 207, the second gate insulating layer 209, and the third interlayer insulating layer 210. The second dam part FDM may be configured to prevent or reduce instances of cracks occurring in the substrate 100 in the bending area BA.

The second dam part FDM may include at least one layer. As an example, the at least one layer may include at least one of a first upper layer FDM-1, a second upper layer FDM-2, a third upper layer FDM-3, a fourth upper layer FDM-4, or a fifth upper layer FDM-5. In this case, the first upper layer FDM-1 may include the first organic insulating layer 211, the second upper layer FDM-2 may include the second organic insulating layer 212, the third upper layer FDM-3 may include the third organic insulating layer 213, the fourth upper layer FDM-4 may include the bank layer 215, and the fifth upper layer FDM-5 may include the spacer 217.

The protective layer 900 may be located at least between the second dam part FDM and the pad terminal 1200, and between the pad terminal 1200 and the terminal section 50. In this case, the protective layer 900 may include photocurable resin. As an example, the protective layer 900 may include resin cured when an ultraviolet ray is irradiated thereto.

The protective layer 900 may be located on at least a portion of the lateral surfaces of the terminal section 50. In addition, the protective layer 900 may be located on at least a portion of the lateral surfaces of the second dam part FDM. In this case, according to some embodiments, a position on which the protective layer 900 is located is not limited thereto and the protective layer 900 may be located between the lateral surface of the terminal section 50 and the lateral surface of the second dam part FDM. In this case, the protective layer 900 may be formed to expose the upper portion of the pad terminal 1200 to the outside. Hereinafter, for convenience of description, the case where the protective layer 900 is located between the lateral surface of the second dam part FDM and the lateral surface of the terminal section 50 is mainly described in detail.

As shown in FIG. 5A, a planar shape of the protective layer 900 may be a ring shape (e.g., a closed-loop form). In this case, an opening area may be formed in the central portion of the protective layer 900. The planar shape of the protective layer 900 is not limited thereto and may have various shapes such as an elliptical shape, a circular shape, a polygon, a polygon with round edges, an irregular shape, or a shape including irregularities.

As shown in FIG. 5B, the protective layer 900 may be provided in plurality, and at least some of the plurality of protective layers 900 may be arranged to be apart from each other on an arbitrary closed circuit. The remaining other protective layers 900 may be arranged inside an arbitrary closed circuit.

The pad terminal section including the pad terminals 1200 is arranged between one lateral side of the substrate 100 on which the terminal section 50 is located, and the display area DA. The pad terminals 1200 may be arranged to form a column in the x direction. According to some embodiments, although FIG. 5 shows the pad terminals 1200 arranged in two columns, the disclosure is not limited thereto. According to some embodiments, the pad terminals 1200 may be arranged to form three or more columns.

The pad terminal 1200 may extend in an oblique direction ob forming an acute angle with respect to each of the x direction and a y direction. According to some embodiments, the pad terminal 1200 may have a planar shape roughly similar to a parallelogram. A portion of the pad terminal 1200 may be electrically connected to a signal line, for example, the data line DL arranged in the display area DA through the connection line 1100. The connection line 1100 and the data line DL may be connected to each other through a contact hole CNT formed in at least one insulating layer located therebetween. Another portion of the pad terminal 1200 may be electrically connected to the terminal section 50 through an outer connection line 1300.

The integrated circuit element 40 may overlap the pad terminal 1200. The integrated circuit element 40 may be electrically connected to the pad terminal 1200 by a conductive adhesive layer such as an anisotropic conductive film.

The pad terminal 1200 may include a stack structure of a plurality of conductive layers. As an example, the pad terminal 1200 may include a first pad conductive layer and a second pad conductive layer. In this case, the first pad conductive layer may include the same material as that of the node connection line 166 described above with reference to FIG. 4. The second pad conductive layer may include the same material as that of the data line DL and/or the driving voltage line PL described above with reference to FIG. 4.

The first pad conductive layer may be in direct contact with the second pad conductive layer and connected to the display area DA through the connection line 1100. An inorganic insulating layer (e.g., at least one of the buffer layer 201, the first gate insulating layer 203, the first interlayer insulating layer 205, the second interlayer insulating layer 207, the second gate insulating layer 209, or the third interlayer insulating layer 210) may be located between the first pad conductive layer and the second pad conductive layer. In addition, an organic insulating layer (e.g., at least one of the first organic insulating layer 211, the second organic insulating layer 212, the third organic insulating layer 213, the bank layer 215, or the spacer 217) exposing at least a portion of the second pad conductive layer may be located on the second pad conductive layer.

The integrated circuit element 40 may be located over the pad terminal 1200, and a bump 42 of the integrated circuit element 40 may be electrically connected to the pad terminal 1200 by an anisotropic conductive film including a conductive ball.

In this case, the terminal section 50 may be connected to the flexible printed circuit board 80 by an anisotropic conductive film. In this case, the terminal section 50 may be connected to the flexible printed circuit board 80 by an anisotropic conductive film.

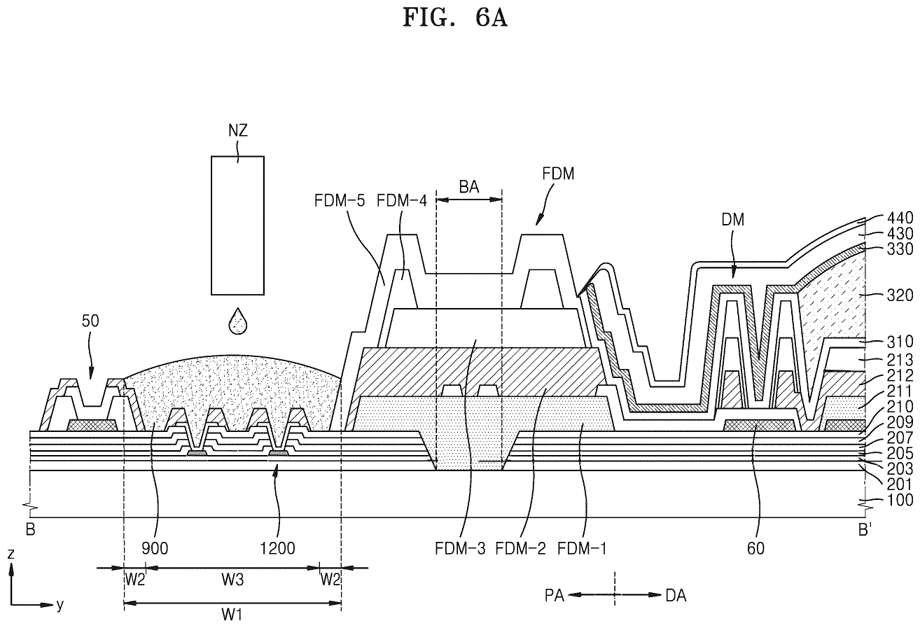

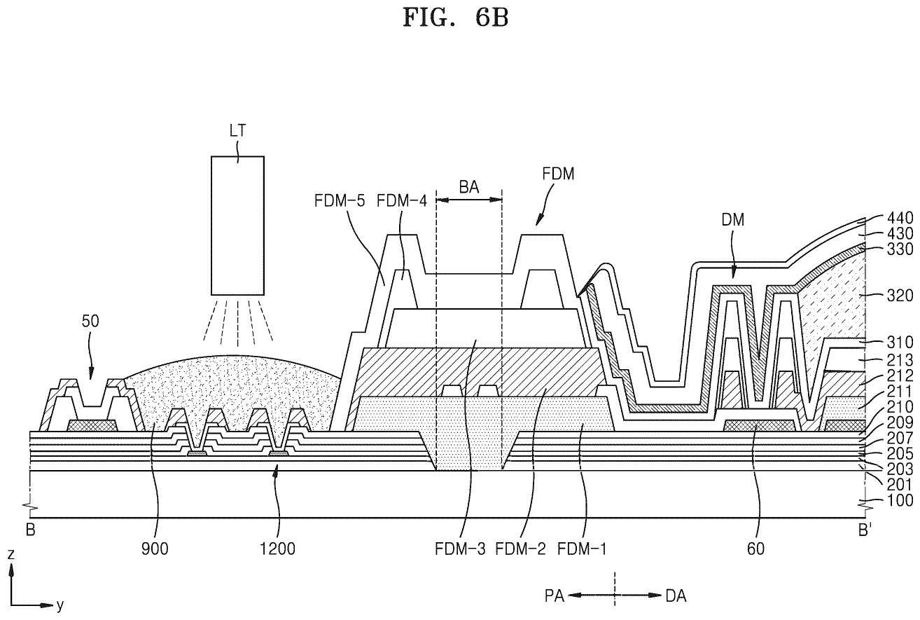

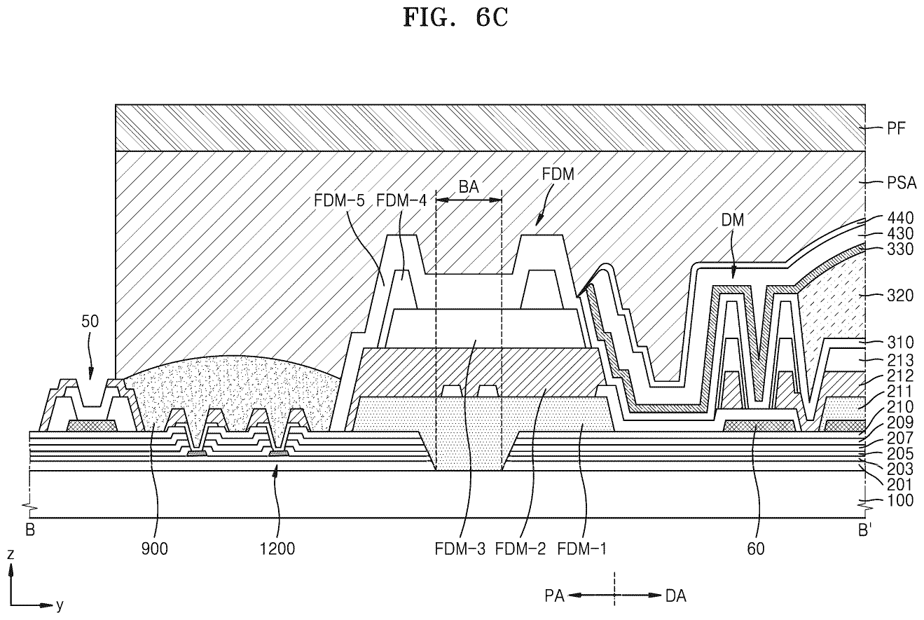

FIGS. 6A to 6C are cross-sectional views showing an order of manufacturing the display panel 10 shown in FIG. 2.

Referring to FIG. 6A, the protective film 900 may be injected to the pad terminal 1200 through a nozzle NZ on the display panel 10. In this case, the nozzle NZ may be configured to supply the protective layer 900 while moving in various directions. The protective layer 900 in a liquid state may be located between the second dam part FDM and the terminal section 50 to completely shield the pad terminal 1200.

The protective layer 900 located on the pad terminal 1200 may move to two opposite sides of the pad terminal 1200. In this case, the height of the protective layer 900 may be the highest in the central region thereof and may decrease from the central region to the end of the protective layer 900. The adhesive force of the central portion of the protective layer 900 may be different from the adhesive force of the edge region of the protective layer 900. As an example, the adhesive force of the edge region of the protective layer 900 may be in a range of 10 gf/inch to 150 gf/inch (or about 10 gf/inch to about 150 gf/inch), and the adhesive force of the central region of the protective layer 900 may be in a range of 5 gf/inch (or about 5 gf/inch) to 10 gf/inch (or about 10 gf/inch).

A first distance W2 (or a width) of the edge region of the protective layer 900 may be in a range of 0.1 or less and greater than 0 of a total length W1 (or a width) of the protective layer 900. In addition, a second distance W3 (or a width) of the central region of the protective layer 900 may be 0.9 or more of the total length W1 (or the width) of the protective layer 900. In this case, the edge region of the protective layer 900 may denote a region from the end of the protective layer 900 to the end of the central region of the protective layer 900. That is, the first distance W2 (or the width) of the protective layer 900 may denote a distance from the end of the protective layer 900 to the boundary between the edge region of the protective layer 900 and the central region of the protective layer 900.

Referring to FIG. 6B, the protective layer 900 is located, and then, light may be irradiated to the protective layer 900 using a light source LT. The protective layer 900 is cured to completely shield the pad terminal 1200. In addition, the protective layer 900 may not be located on the terminal section 50.

Referring to FIG. 6C, a protective film may be arranged in the peripheral area PA in which the protective layer 900 is arranged, and the display area DA. In this case, the protective film may include a protective film base PF and an adhesive layer PSA. The protective film base PF may include at least one of polyethylene terephthalate, polypropylene, polycarbonate, polyethylene, or polyvinyl chloride. In addition, the adhesive layer PSA may include at least one of silicon, acryl or polyurethane.

The display panel 10 to which the protective film is attached may be supplied to the outside, or a separate process may be performed again. In this case, the protective film may be removed to form the integrated circuit element 40. In the case where the protective film is removed, at least a portion of the protective layer 900 may be removed. Particularly, when the protective film is removed, the central region of the protective layer 900 may be removed together with the protective film. In this case, the pad terminal 1200 may be exposed to the outside. Next, the integrated circuit element 40 may be attached to the pad terminal 1200 by forming the integrated circuit element 40 on the pad terminal 1200. In this case, the protective layer 900 may be completely removed by the protective film or partially remain. As an example, the protective layer 900 may be located on the display panel 10 as shown in FIG. 4. In this case, to completely remove the protective layer 900, a removal film of a similar form to the protective film may be used. In this case, the removal film may be configured to remove the protective layer 900 by being in contact with the protective layer 900. According to some embodiments, the protective layer 900 may be removed by providing plasma to the protective layer 900.

In this case, the protective layer 900 may prevent or reduce damage to the pad terminal 1200 when removing the protective film. That is, in the case where the protective layer 900 is not present, the pad terminal 1200 may be in direct contact with the adhesive layer PSA, and the pad terminal 1200 may be damaged by the adhesive force of the adhesive layer PSA. In this case, the integrated circuit element 40 and the pad terminal 1200 may not be in contact with each other, or even though they are in contact with each other, poor contact may occur between the integrated circuit element 40 and the pad terminal 1200, causing the display panel 10 itself not to operate. In contrast, when the protective layer 900 is located on the pad terminal 1200 and then the protective film is attached thereon, the protective layer 900 is separated from the pad terminal 1200 when removing the protective film. Accordingly, damage to the pad terminal 1200 when removing the protective film may be prevented or reduced.

In addition, a polarizing film may be attached to the display panel 10 after removing the protective film. The polarizing film may be located on the input sensing layer.

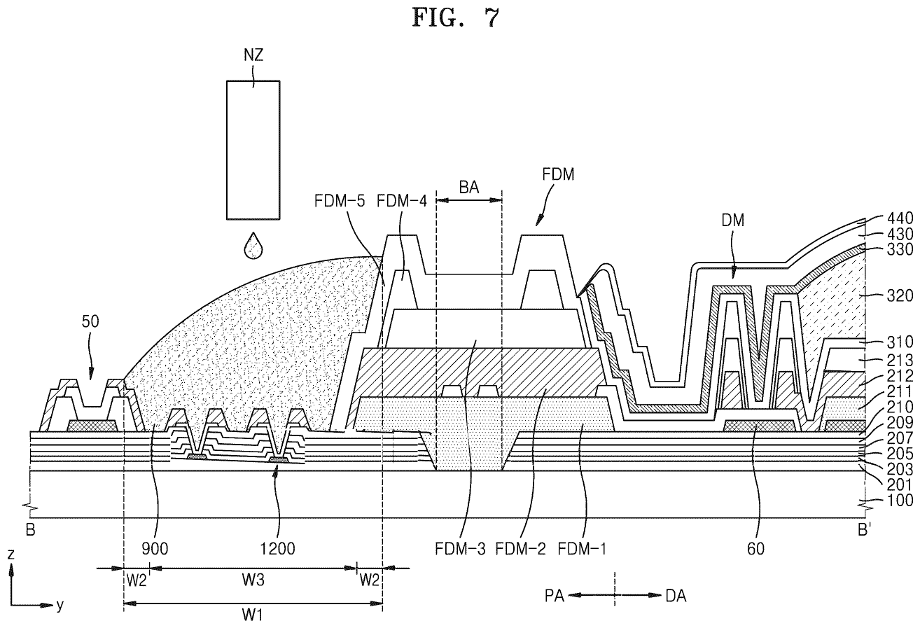

FIG. 7 is a cross-sectional view showing a portion of an order of manufacturing a display panel according to some embodiments.

Referring to FIG. 7, the display panel 10 may include the sub-pixel circuit, the light-emitting diode, the first dam part DM, the second dam part FDM, the pad terminal 1200, the terminal section 50, and the protective layer 900. In this case, because the sub-pixel circuit, the light-emitting diode, the first dam part DM, the second dam part FDM, the pad terminal 1200, and the terminal section 50 are identical or similar to those described with reference to FIGS. 4A to 5, detailed descriptions thereof are omitted.

The protective layer 900 may be located on the pad terminal 1200 through the nozzle NZ. In this case, the protective layer 900 may be in contact with the lateral surface of the fifth upper layer FDM-5 located on the first upper layer FDM-1, the second upper layer FDM-2, the third upper layer FDM-3, and the fourth upper layer FDM-4. In this case, the second distance W3 in which the central region of the protective layer 900 is formed, and the first distance W2 may be similar to those described above. That is, the first distance W2 of the edge region of the protective layer 900 may be in a range of 0 (or about 0) to 0.1 (or about 0.1) of the total length W1. In addition, the adhesive force of the central region of the protective layer 900 may be different from the adhesive force of the edge region of the protective layer 900. In this case, the adhesive force of the central region of the protective layer 900 and the adhesive force of the edge region of the protective layer 900 may be the same as those described above.

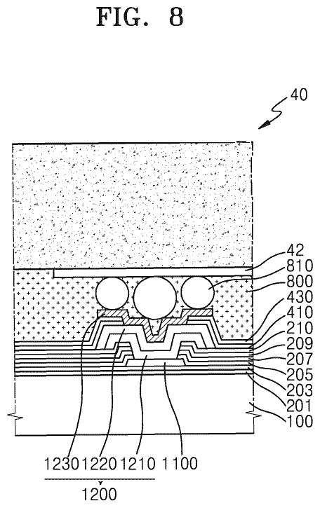

FIG. 8 is a cross-sectional view of a pad terminal of the display panel 10 according to some embodiments.

Referring to FIG. 8, the pad terminal 1200 may include a stack structure of a plurality of conductive layers. As an example, as shown in FIG. 8, the pad terminal 1200 may include a first pad conductive layer 1210, a second pad conductive layer 1220, and a third pad conductive layer 1230.

The first pad conductive layer 1210 may include the same material as that of the node connection line 166 described above with reference to FIG. 4. The second pad conductive layer 1220 may include the same material as that of the data line DL and/or the driving voltage line PL described above with reference to FIG. 4. The third pad conductive layer 1230 may include the same material as that of the first conductive line 420 and/or the second conductive line 440 described above with reference to FIG. 4. The third pad conductive layer 1230 may be connected to the second pad conductive layer 1220 through a contact hole formed in the first and second touch insulating layers 410 and 430.

Although it is shown in FIG. 8 that the first pad conductive layer 1210 and the second pad conductive layer 1220 are in direct contact with each other, and the insulating layer (e.g., the first and second touch insulating layers 410 and 430) is located between the second pad conductive layer 1220 and the third pad conductive layer 1230, the disclosure is not limited thereto. According to some embodiments, an insulating layer (e.g., an organic insulating layer) may be located between the first pad conductive layer 1210 and the second pad conductive layer 1220, and the first pad conductive layer 1210 may be connected to the second pad conductive layer 1220 through a contact hole of the relevant insulating layer.

The integrated circuit element 40 may be electrically connected to the pad terminal 1200 by an anisotropic conductive film (ACF) 800 including a conductive ball 810. Because the bump 42 of the integrated circuit element 40 overlaps the pad terminal 1200, and the conductive ball 810 is located therebetween, the bump 42 may be electrically connected to the pad terminal 1200.

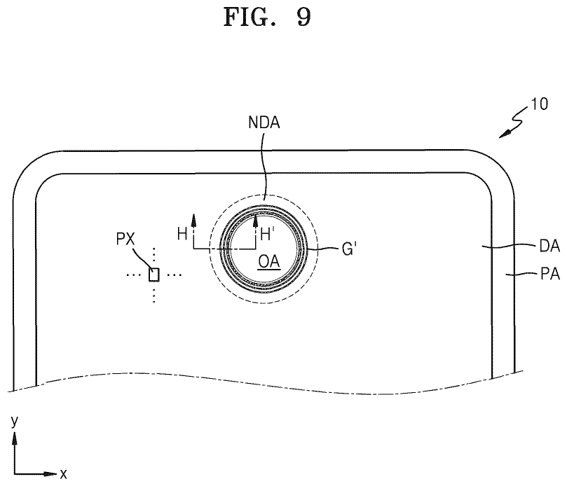

FIG. 9 is a plan view of a portion of the display panel 10 according to some embodiments.

Referring to FIG. 9, the display panel 10 may include an opening area OA arranged inside a front display area FDA, and a non-display area NDA surrounding the opening area OA.

The planar shape of the opening area OA may have various shapes such as a circular shape, an elliptical shape, a polygon including a quadrangle, a star shape, or a diamond shape. In addition, the position of the opening area OA may be variously changed. As an example, the opening area OA may be arranged in the upper center of the front display area FDA as shown in FIG. 9, or, unlike the drawing, may be arranged in the right center or left center of the front display area FDA, and may be modified variously.

A component 600, which is an electronic element, may be located below the display panel 10 to correspond to the opening area OA. The component 600 is a camera that uses an infrared ray or visible ray and may include an imaging element. Alternatively, the component 600 may include a solar battery, a flash, an illuminance sensor, a proximity sensor, and an iris sensor. Alternatively, the component 600 may have a function of receiving sound.

Referring to FIG. 9 again, the non-display area NDA may surround the opening area OA. The non-display area NDA is a region in which a display element such as a light-emitting element emitting light is not arranged. Signal lines configured to provide signals to the sub-pixels PX provided near the opening area OA may pass through the non-display area NDA, or an additional groove G′ may be arranged in the non-display area NDA.

Although it is shown in FIG. 9 that three additional grooves G′ are positioned in the non-display area NDA, the disclosure is not limited thereto. According to some embodiments, one, two, four or more grooves may be positioned in the non-display area NDA.

The additional grooves G′ may have a ring shape entirely surrounding the opening area OA in the non-display area NDA. The diameter of each of the additional grooves G′ may be greater than the diameter of the opening area OA. In a plan view, the additional grooves G surrounding the opening area OA may be apart by a preset interval from each other.

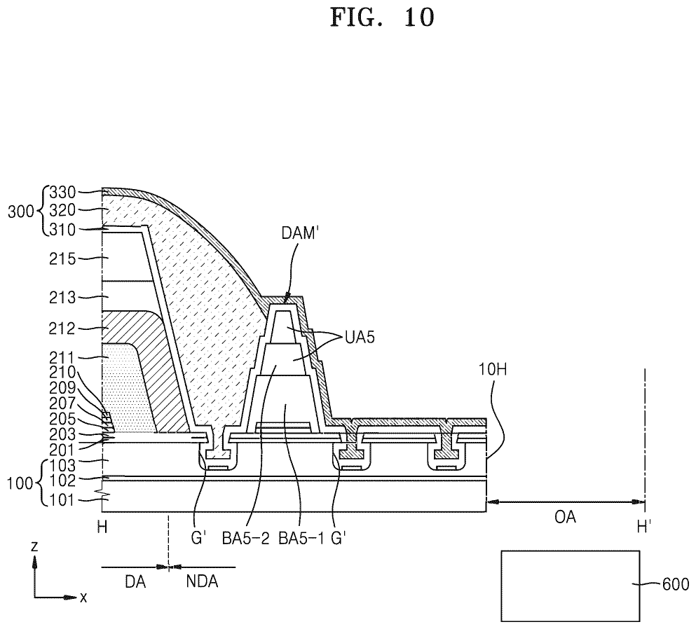

FIG. 10 is a cross-sectional view of a portion of the display panel 10, taken along the line H-H′ of FIG. 9.

Referring to FIG. 10, as described above, the display panel 10 may include the sub-pixel circuit, the light-emitting diode, the first dam part, the second dam part, the pad terminal, and the terminal section arranged in the display area DA. In this case, because the sub-pixel circuit, the light-emitting diode, the first dam part, the second dam part, the pad terminal, and the terminal section are identical or similar to those described with reference to FIGS. 3 to 5, detailed descriptions thereof are omitted.

The display panel 10 may include a first opening 10H corresponding to the opening area OA.

The plurality of additional grooves G′ may be arranged in the non-display area NDA. The additional groove G′ may be formed by spatially connecting a recess obtained by removing a portion of a second base layer 103 of the substrate 100 to a hole passing through an inorganic insulating layer. In this case, the substrate 100 may include a first base layer 101, an inorganic barrier layer 102, and the second base layer 103. The first base layer 101 and the second base layer 103 may each include a polymer resin. The polymer resin may include at least one of polyethersulfone (PES), polyacrylate (PAR), polyetherimide (PEI), polyethylene naphthalate (PEN), polyethylene terephthalate (PET), polyphenylene sulfide (PPS), polyarylate, polyimide (PI), polycarbonate, cellulose triacetate (TAC), or cellulose acetate propionate (CAP). In addition, the inorganic insulating layer may include at least one of the buffer layer 201, the first gate insulating layer 203, the first interlayer insulating layer 205, the second interlayer insulating layer 207, the second gate insulating layer 209, or the third interlayer insulating layer 210. Hereinafter, for convenience of description, the case where the inorganic insulating layer includes the buffer layer 201 and the first gate insulating layer 203 is mainly described in detail. An organic insulating layer may be located on the inorganic insulating layer. In this case, the organic insulating layer may include at least one of a first organic insulating layer 211, a second organic insulating layer 212, a third organic insulating layer 213, the bank layer 215, or the spacer 217.

The inorganic insulating layer may include a protrusion tip protruding toward the additional groove G′. At least one of the organic layer or the opposite electrode that may be included in the organic light-emitting diode may be disconnected around the additional groove G′ by the protruding tip of the inorganic insulating layer.

An additional dam DAM′ may be arranged in the non-display area NDA, and the additional dam DAM′ may block flow of the organic encapsulation layer 320. The first inorganic encapsulation layer 310 and the second inorganic encapsulation layer 330 may be in contact with each other between the additional dam DAM′ and the opening area OA. In this case, the additional dam DAM′ may have a shape identical or similar to that of one of the first dams DM described above.

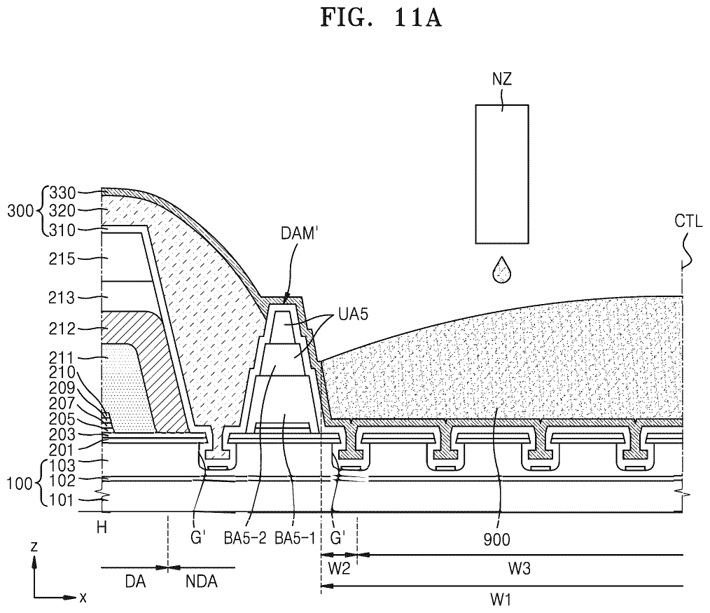

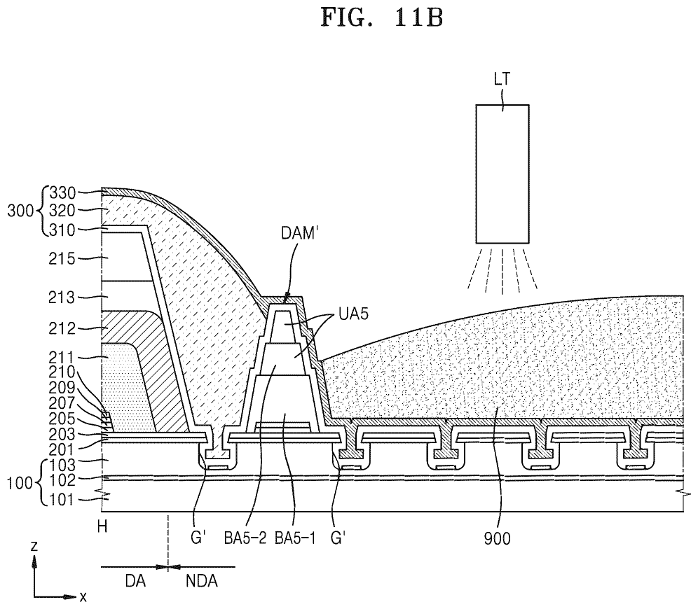

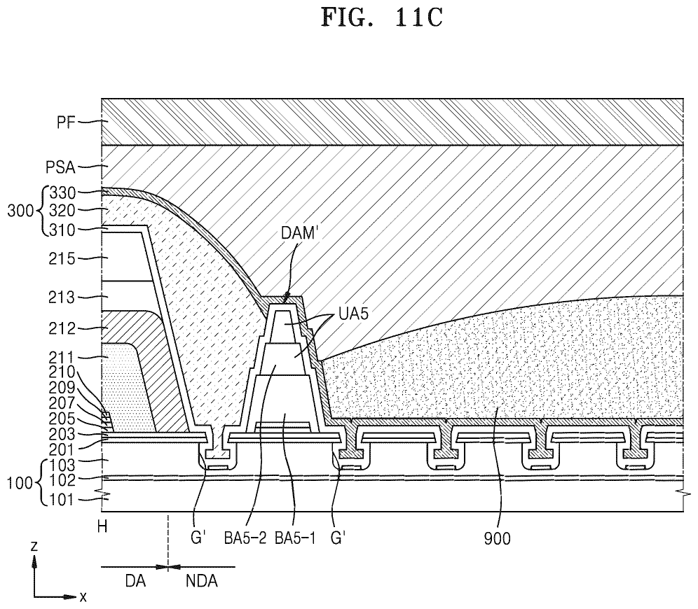

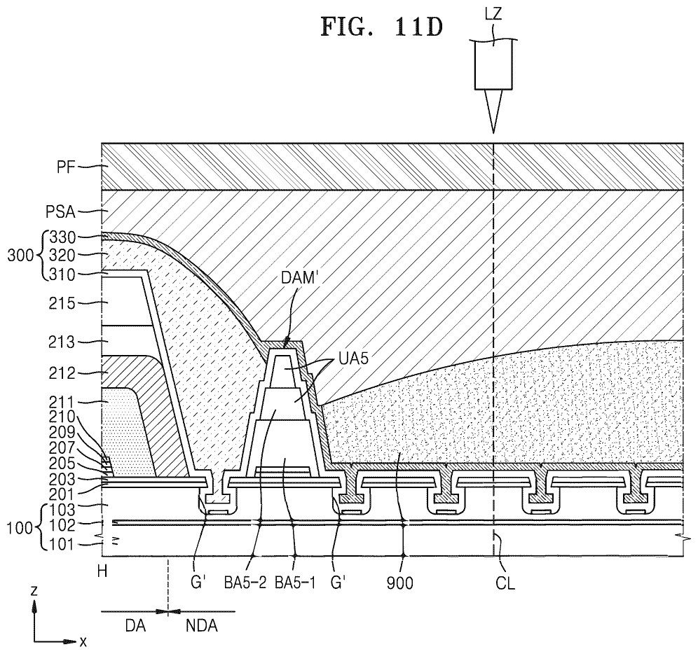

FIG. 11A is a cross-sectional view showing an order of manufacturing the display panel 10 shown in FIG. 9.

Referring to FIG. 11A, the protective layer 900 may be located on the upper surface of the additional groove G′ of the display panel 10 through the nozzle NZ. In this case, the protective layer 900 may be in a liquid state and configured to shield the additional groove G′ entirely. The content shown in FIG. 11A may be symmetrical with respect to a central line CLT. In this case, the protective layer 900 may entirely shield a portion in which the opening area shown in FIG. 10 is to be formed.

FIG. 11B is a cross-sectional view showing an order of manufacturing the display panel 10 shown in FIG. 9.

Referring to FIG. 11B, the protective layer 900 may be cured through the light source LT. In this case, the light source LT may be configured to irradiate an ultraviolet ray to the protective layer 900. The protective layer 900 may be cured in a liquid state by the light source LT.

As described above, the protective layer 900 may be formed in the central region and the edge region. In this case, the first distance W2 in the edge region and the second distance W3 in the central region may be similar to those described above. That is, the first distance W2 in the edge region may be in a range of 0 (or about 0) to 0.1 (or about 0.1) of the entire distance W1 of the protective layer 900.

In addition, the adhesive force of the protective layer 900 in the central region and the adhesive force of the protective layer 900 in the edge region may be identical or similar to those described above.

FIG. 11C is a cross-sectional view showing an order of manufacturing the display panel 10 shown in FIG. 9.

Referring to FIG. 11C, the protective film may be located on the display panel 10 on which the protective layer 900 is formed. In this case, the protective film may include the protective film base PF and the adhesive layer PSA. Because the protective film base PF and the adhesive layer PSA are identical or similar to those described above, detailed descriptions thereof are omitted.

The adhesive layer PSA may be in direct contact with the upper surface of the protective layer 900. That is, the adhesive layer PSA may be formed to cover the entire upper surface of the protective layer 900.

FIG. 11D is a cross-sectional view showing an order of manufacturing the display panel 10 shown in FIG. 9.

Referring to FIG. 11D, the opening area shown in FIG. 10 may be formed by irradiating a laser beam through a laser irradiation part LZ with the protective film base PF and the adhesive layer PSA arranged and forming a cutting line CL. In this case, the laser beam may be configured to sequentially pass through the protective film base PF, the adhesive layer PSA, and the protective layer 900 to cut the substrate 100. In this case, the additional groove G may be configured to prevent or reduce cracks of the substrate 100 from propagating due to the laser beam.

When the above process is completed, the protective film base PF and the adhesive layer PSA may be removed. In this case, the adhesive layer PSA may be configured to remove at least a portion of the protective layer 900 by being in contact with the protective layer 900. In this case, when removing the protective film base PF, the protective layer 900 may be completely removed together with the adhesive layer PSA, or at least a portion of the protective layer 900 may remain on the display panel 10.

In the case where the protective layer 900 remains, at least a portion of the protective layer 900 arranged in the edge region of the protective layer 900 may remain. In this case, according to some embodiments, a remaining portion of the protective layer 900 may be located on the lateral surface of the additional dam DAM′.

In the case where the protective layer 900 remains, a remaining portion of the protective layer 900 may be arranged in a ring shape similar to the additional groove G′ shown in FIG. 10. According to some embodiments, the protective layer 900 may be arranged to be apart from each other on an arbitrary ring shape similar to the outer portion of the additional groove G′.

In the case where the protective layer 900 remains, the protective layer 900 may be completely removed through a separate removal film or plasma.

Accordingly, because the protective layer 900 is formed, damage to the display panel 10 when forming the opening area may be prevented or reduced. In addition, because the protective layer 900 is mostly removed after the opening area is formed, the protective layer 900 may not deteriorate the function of a component.

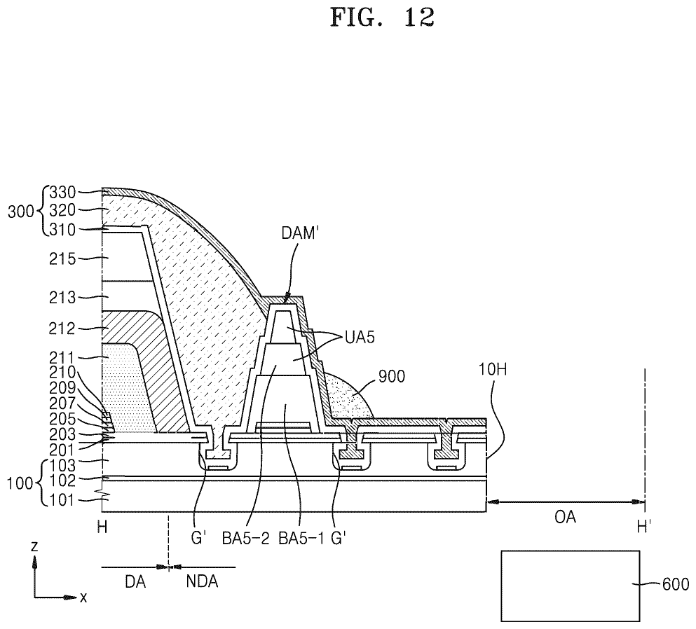

FIG. 12 is a plan view of a portion of the display panel 10 according to some embodiments.

Referring to FIG. 12, as described above, the display panel may include the sub-pixel circuit, the light-emitting diode, the first dam part, the second dam part, the pad terminal, the additional dam DAM′, the additional groove G′, and the protective layer arranged in the display area DA. In this case, because the sub-pixel circuit, the light-emitting diode, the first dam part, the second dam part, the pad terminal, and the terminal section are identical or similar to those described with reference to FIGS. 3 to 5, detailed descriptions thereof are omitted.

The display panel 10 may include the first opening 10H corresponding to the opening area OA. In this case, a plurality of additional grooves G′ may be arranged in the non-display area NDA. The additional groove G′ may be formed by spatially connecting a recess obtained by removing a portion of the second base layer 103 of the substrate 100 to a hole passing through an inorganic insulating layer. In this case, the substrate 100 may include the first base layer 101, the inorganic barrier layer 102, and the second base layer 103. The first base layer 101, the inorganic barrier layer 102, and the second base layer 103 may be identical or similar to those described above. The inorganic insulating layer may include at least one of the buffer layer 201, the first gate insulating layer 203, the first interlayer insulating layer 205, the second interlayer insulating layer 207, the second gate insulating layer 209, or the third interlayer insulating layer 210. Hereinafter, for convenience of description, the case where the inorganic insulating layer includes the buffer layer 201 and the first gate insulating layer 203 is mainly described in detail. An organic insulating layer may be located on the inorganic insulating layer. In this case, the organic insulating layer may include at least one of a first organic insulating layer 211, a second organic insulating layer 212, a third organic insulating layer 213, the bank layer 215, or the spacer 217.

The protective layer 900 may be located on the lateral surface of the additional dam DAM′. In this case, the protective layer 900 may be arranged in the non-display area NDA. In addition, the protective layer 900 may be arranged in a position that does not overlap the component as much as possible. In this case, the protective layer 900 may be formed in a closed loop shape similar to the additional groove G′ or may be arranged to be apart from each other on the closed loop.

The electronic apparatus and the display panel according to some embodiments may be configured to maintain electrical connection between the integrated circuit element and the pad terminal.

In the method of manufacturing the display panel according to some embodiments, damage to the pad terminal may be prevented or reduced.

In the method of manufacturing the display panel according to some embodiments, the protective layer may be formed simply and swiftly.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope of embodiments according to the present disclosure as defined by the following claims, and their equivalents.

What is claimed is:

1. A display panel comprising:
a substrate including a display area and a peripheral area outside the display area;
a pad terminal section on the substrate;
a driving element on the pad terminal section; and
a protective layer on the substrate and spaced apart from the pad terminal section.

2. The display panel of claim 1, wherein the protective layer has a closed loop shape to surround the pad terminal section.

3. The display panel of claim 1, wherein the protective layer is provided in plurality, and the plurality of protective layers are on a closed loop surrounding the pad terminal section.

4. The display panel of claim 1, further comprising a terminal section on the substrate and spaced apart from the pad terminal section,
wherein at least a portion of the protective layer is on a lateral surface of the terminal section.

5. The display panel of claim 1, further comprising a bending area in the peripheral area and bending.

6. The display panel of claim 5, further comprising a dam part in the bending area, wherein at least a portion of the protective layer is on a lateral surface of the dam part.

7. The display panel of claim 1, wherein the substrate further includes:
an opening area in the display area; and
a non-display area surrounding at least a portion of the opening area,
wherein the protective layer is in the non-display area.

8. The display panel of claim 1, wherein an adhesive force of the protective layer is in a range of 10 gf/inch and 150 gf/inch.

9. The display panel of claim 1, wherein the protective layer is cured by an ultraviolet ray.

10. An electronic apparatus comprising:
a display panel displaying image;
wherein the display panel comprises:
a substrate including a display area and a peripheral area outside the display area;
a pad terminal section on the substrate;
a driving element on the pad terminal section; and
a protective layer on the substrate and spaced apart from the pad terminal section.

11. The electronic apparatus of claim 10, wherein the protective layer has a closed loop shape to surround the pad terminal section.

12. The electronic apparatus of claim 10, wherein the protective layer is provided in plurality, and the plurality of protective layers are on a closed loop surrounding the pad terminal section.

13. The electronic apparatus of claim 10, wherein the display panel further comprises a terminal section on the substrate and spaced apart from the pad terminal section,
wherein at least a portion of the protective layer is on a lateral surface of the terminal section.

14. The electronic apparatus of claim 10, wherein the display further comprises a bending area in the peripheral area and bending.

15. The electronic apparatus of claim 14, wherein the display further comprises a dam part in the bending area, wherein at least a portion of the protective layer is on a lateral surface of the dam part.

16. The electronic apparatus of claim 10, wherein the substrate further includes:
an opening area in the display area; and
a non-display area surrounding at least a portion of the opening area,
wherein the protective layer is in the non-display area.

17. The electronic apparatus of claim 10, wherein an adhesive force of the protective layer is in a range of 10 gf/inch and 150 gf/inch.

18. The electronic apparatus of claim 10, wherein the protective layer is cured by an ultraviolet ray.

19. The electronic apparatus of claim 10, wherein the electronic apparatus is one of mobile phones, smartphones, tablet personal computers, mobile communication terminals, electronic organizers, electronic books, portable multimedia players (PMPs), navigations, ultra mobile personal computers (UMPCs), televisions, notebook computers, monitors, advertisement boards, Internet of things (IoTs) device, smartwatches, watchphones, glasses-type displays, head-mounted displays (HMDs), instrument panels for automobiles, center fascias for automobiles, center information displays (CIDs) arranged on a dashboard, room mirror displays that replace side mirrors of automobiles, an entertainment system arranged on the backside of front seats for backseat passengers in automobiles, a head-up display (HUD) installed at the front of a vehicle or projected on a front window glass, or a computer generated hologram augmented reality head up display

20. A method of manufacturing a display panel, the method comprising:
arranging a protective layer on a substrate;
curing the protective layer using an ultraviolet ray;
arranging a protective film on the substrate; and
removing at least a portion of the protective layer by removing the protective film.

21. The method of claim 20, wherein the protective layer is configured to shield a pad terminal section on the substrate.

22. The method of claim 20, wherein an adhesive force of a first region of the protective layer is different from an adhesive force of a second region of the protective layer outside the first region.

23. The method of claim 22, wherein the adhesive force of the first region is less than the adhesive force of the second region.

24. The method of claim 22, wherein the adhesive force of the first region is in a range of 5 gf/inch to 10 gf/inch, and the adhesive force of the second region is in a range of 10 gf/inch to 150 gf/inch.

25. The method of claim 22, wherein a distance from an end of the protective layer to a boundary between the first region and the second region is 0.1 or less of a total length of the protective layer.

26. The method of claim 20, wherein the protective layer is supplied through a nozzle.

27. The method of claim 20, wherein the protective film includes:
a protective film base; and
an adhesive layer between the protective film base and the substrate.

28. The method of claim 27, wherein the protective film base includes at least one of polyethylene terephthalate, polypropylene, polycarbonate, polyethylene, or polyvinyl chloride.

29. The method of claim 27, wherein the adhesive layer includes at least one of silicon, acryl, or polyurethane.

30. The method of claim 20, further comprising removing at least a portion of the protective film, at least a portion of the protective layer, and at least a portion of the substrate by irradiating a laser beam to the protective film.
